(19) United States
(12) Patent Application Publication
(10) Pub. No.: US 2007/0141827 A1
(43) Pub. Date: Jun. 21, 2007

(54) METHOD FOR FORMING COPPER LINE

(76) Inventor: Kyu Cheol Shim, Seoul (KR)

Correspondence Address: SHERR & NOURSE, PLLC, 620 HERNDON PARKWAY, SUITE 200, HERNDON, VA, 20170, US

(21) Appl. No.: 11/609,874

(22) Filed: Dec. 12, 2006

(30) Foreign Application Priority Data
Dec. 16, 2005 (KR) 10-2005-0124453

(51) Int. Cl. H01L 21/4763

(52) U.S. Cl. 438/618; 257/E21.081

(57) ABSTRACT

Embodiments relate to a method for forming a copper line. According to embodiments, the method may include forming an insulation layer on a semiconductor substrate, forming a copper line pattern on the insulation layer, and forming a copper line; removing a copper oxide layer through a reactive preclean process, the copper oxide layer being formed on a surface of the copper line in the step of forming the copper line, and depositing a capping layer covering the copper line and the insulation layer without the reactive preclean process and vacuum interruption.

The present application claims priority under 35 U.S.C. 119 and 35 U.S.C. 365 to Korean Patent Application No. 10-2005-0124453 (filed on Dec. 16, 2005), which is hereby incorporated by reference in its entirety.

### BACKGROUND

Embodiments relate to a method for forming a copper line in a semiconductor device and to a method for manufacturing a copper line in a semiconductor device.

A multilayer wiring method has previously been developed to form a copper line with low resistance by using a damascene process. For example, an insulation layer may be formed on a semiconductor substrate, and a dual damascene pattern may be formed by patterning the insulation layer, for example through photolithography and etching processes. The dual damascene pattern may be formed through a via-first scheme or a trench first scheme, for example.

A barrier layer and a seed layer may be formed on the dual damascene pattern, for example through a sputtering method. A copper layer for gap-filling the dual damascene pattern may be deposited, for example through an electric chemical plating method, and a copper line may be formed through a planarization process.

Plasma surface processing may be performed, for example using a chemical vapor deposition method, and a capping layer may be deposited.

These processes may be sequentially repeated to form a multilayer wiring.

However, after forming the copper line, a copper oxide CuOₓ layer may form on a surface of the copper line.

The copper oxide layer may form through a reaction of the copper line and oxygen. For example, the copper line may be exposed to oxygen in the air or to a small quantity of oxygen remaining within a vacuum chamber, or the copper line shifting a semiconductor substrate within an air atmosphere among process chambers in an atmospheric state.

According to related art, to remove the copper oxide layer, a plasma surface processing may be performed, for example using a chemical vapor deposition method, and a capping layer may be deposited. However, the copper oxide layer may not be effectively removed through the surface processing.

Since the copper oxide layer may not be completely removed, wiring resistance may increase and electromigration resistance may decrease. This could result in a device failure.

According to related art, after the copper line is formed, a by-product may be formed on a surface of the copper line, in addition to the copper oxide layer. Such a by-product may increase the resistance of the wiring and may reduce adhesion with a subsequent layer.

### SUMMARY

Embodiments relate to a method for forming a copper line that may prevent a device failure from occurring due to a copper oxide layer.

Embodiments relate to a method for forming a copper line that may prevent a device failure from occurring by removing a by-product generated in a process of forming the copper line, and may improve adhesion.

According to embodiments, a method for forming a copper line may include forming an insulation layer on a semiconductor substrate, forming a copper line pattern on the insulation layer, and forming a copper line, removing a copper oxide layer through a reactive preclean process, the copper oxide layer being formed on a surface of the copper line in the step of forming the copper line, and depositing a capping layer covering the copper line and the insulation layer without the reactive preclean process and vacuum interruption.

According to embodiments, a method for forming a copper line may include forming an insulation layer on a semiconductor substrate, forming a copper line pattern on the insulation layer, and forming a copper line, removing a copper oxide layer through a reactive preclean process, the copper oxide layer being formed on a surface of the copper line in the step of forming the copper line, removing a by-product by using a physical method, the by-product being formed on the surface of the copper line in the step of forming the copper line, and depositing a capping layer for covering the copper line and the insulation layer without the by-product removal process and vacuum interruption.

### BRIEF DESCRIPTION OF THE DRAWINGS

FIG. 1 is an example sectional view illustrating a copper line on which a copper oxide layer has been formed according to a method for forming a copper line according to embodiments;

FIG. 2 is an example sectional view of a capping layer formed through a method for forming a copper line according to embodiments;

FIG. 3 is an example sectional view illustrating a copper line on which a copper oxide layer and a by-product have been formed according to a method for forming a copper line according to embodiments; and

FIG. 4 is an example sectional view of a capping layer formed through a method for forming a copper line according to embodiments.

### DETAILED DESCRIPTION OF EMBODIMENTS

Hereinafter, a method for forming a copper line according to embodiments will be described with reference to the accompanying drawings.

In embodiments, a damascene pattern may be shown as a copper line pattern. However, embodiments are not limited to such a damascene pattern.

In embodiments, a copper line may be formed by a dual damascene pattern. Additionally, a copper oxide layer formed on an upper portion of the copper line may be removed, for example by using a reactive preclean process (RF sputter etch), and a capping layer may be formed, for example by using a RF magnetron sputtering method without vacuum interruption.

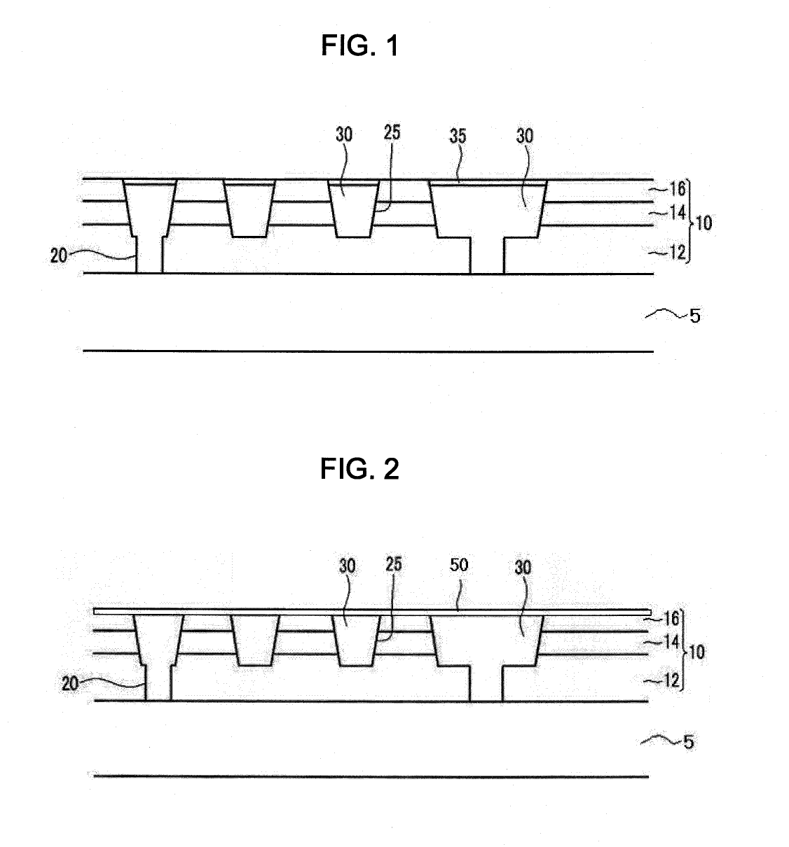

Referring to FIG. 1, in embodiments, insulation layer 10 may be formed on a lower structure (not shown) of semiconductor substrate 5.

The lower structure may include a lower copper line (not shown). Insulation layer 10 may be made from undoped Silicate Glass (USG) layer 12, Fluo Silica Glass (FSG) 14, and USG 16.

Dual damascene pattern 20 may be formed on insulation layer 10, for example through photolithography and etching processes. In embodiments, single damascene pattern 25 may also be formed on insulation layer 10 together with dual damascene pattern 20.

A barrier layer and a seed layer (not shown) may be formed on dual damascene pattern 20, for example by using a sputtering method, and copper layer 30 may be formed by using an electric chemical plating method, for example to gap-fill dual damascene pattern 20.

In embodiments, a degas process may be performed before forming the barrier layer and the seed layer. The degas process may emit and remove gas within semiconductor substrate 5.

After the degas process, a process may be performed to remove copper oxide layer 35 formed on the surface of the lower copper line exposed by dual damascene pattern 20.

After a copper layer may be formed on the damascene patterns, copper line 30, that may be gap-filled in dual damascene pattern 20, may be formed, for example by performing a planarization process.

However, in a process of forming copper line 30, copper oxide layer 35 may form on a surface of copper line 30, for example through a reaction of copper line 30 and the air.

To remove copper oxide layer 35, semiconductor substrate 5, that may include copper line 30, may be arranged in a sputter etch chamber, that may use an Inductively Coupled Plasma (ICP) scheme. A mixture gas formed of an inert gas and a reactive gas may be supplied to the sputter etch chamber, and a reactive preclean process may be performed.

In embodiments, it may be possible to use He gas or Ar gas as the inert gas, and to use H₂ gas as the reactive gas. Further, self DC bias power of −50 to −500V may be used. When the self DC bias power is less than −50V, copper oxide layer 35 may not be easily removed. However, when the self DC bias power exceeds −500V, the semiconductor substrate may be damaged by the plasma.

Referring to FIG. 2, by using the reactive preclean process, copper oxide layer 35, that may be formed on a surface of copper line 30, may be efficiently removed. That is, copper oxide layer 35 may be removed through the reaction of the plasma of the reactive gas or the inert gas, and copper oxide layer 35.

Semiconductor substrate 5 may be shifted to an RF magnetron sputter chamber without interruption of the reactive preclean process and vacuum, and capping layer 50 may be deposited to cover copper line 30 and insulation layer 10.

In this way, capping layer 50 may be deposited without the reactive preclean process and vacuum being interrupted. Accordingly, it may be possible to prevent copper oxide layer 35 from being formed on copper line 30.

When capping layer 50 is deposited, gas for forming capping layer 50 may include pure Ar gas, Ar gas including hydrogen, or N₂ gas. The capping layer made from a silicon nitride layer may be deposited using a reactive sputtering method, for example using Si or SiNₓ target at room temperature (e.g. approximately 21° C.-23° C.) or a temperature below approximately 400° C.

According to such process conditions, it may be possible to easily adjust the physical properties of capping layer 50. If the deposition temperature of capping layer 50 is less than room temperature or exceeds approximately 400° C., it may be difficult to adjust the physical properties of capping layer 50.

According to embodiments, the reactive preclean process may be used to remove the copper oxide layer, and the copper oxide layer may be completely removed. Consequently, it may be possible to reduce or prevent an increase in resistance due to a copper oxide layer and it may also be possible to prevent device failures that may occur due to an increase in resistance.

Further, according to embodiments, after removing the copper oxide layer, the capping layer may be deposited without vacuum interruption, so that it may be possible to prevent the copper oxide layer from being additionally generated. Furthermore, the reactive sputter process may be used for the capping layer deposition process, so that it may be possible to easily adjust the physical properties of the capping layer.

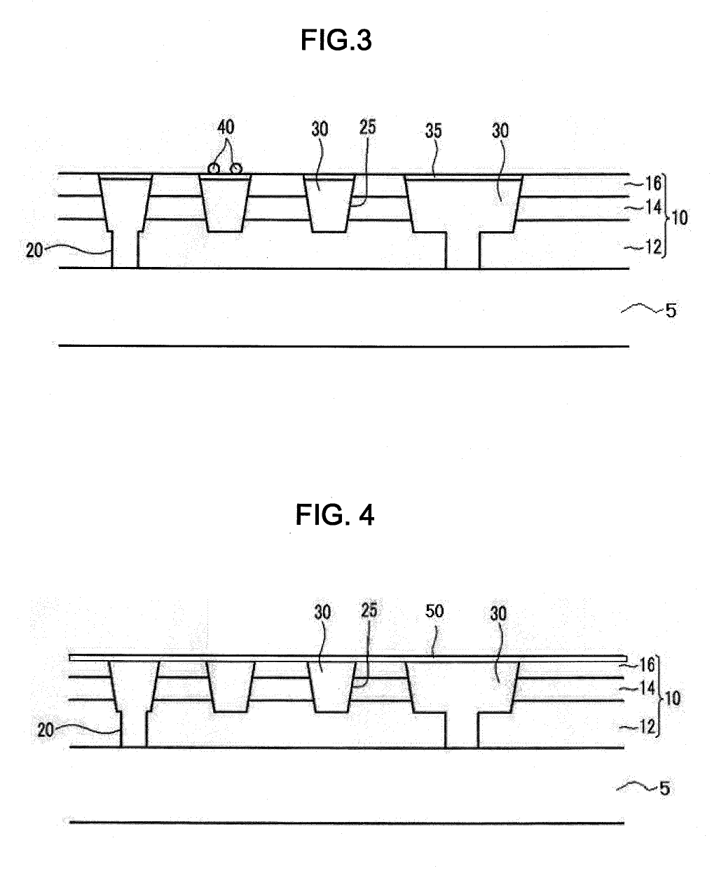

FIG. 3 is an example sectional view illustrating a copper line on which a copper oxide layer and a by-product have been formed according to a method for forming a copper line according to embodiments.

According to embodiments, a copper line may be formed by a dual damascene pattern. A copper oxide layer formed on an upper portion of the copper line may be removed, for example using a reactive preclean process (RF sputter etch), a by-product may be removed, for example using a physical method, and a capping layer may be formed, for example using a RF magnetron sputtering method without vacuum interruption.

Referring to FIG. 3, after forming a copper layer within the damascene pattern, copper line 30, that may be gap-filled in dual damascene pattern 20, may be formed, for example by performing a planarization process

However, in a process of forming copper line 30, copper oxide layer 35 may form on a surface of copper line 30, for example through a reaction of copper line 30 and the air, and by-product 40 may also form.

To remove copper oxide layer 35, semiconductor substrate 5, that may include copper line 30, may be arranged in a sputter etch chamber that may use an ICP scheme. A mixture gas formed of an inert gas and a reactive gas may be supplied to the sputter etch chamber, and a reactive preclean process may be performed.

Referring to FIG. 4, by using the reactive preclean process, copper oxide layer 35, that may have formed on a surface of copper line 30, may be efficiently removed. That is, copper oxide layer 35 may be removed through the reaction of the plasma of the reactive gas or the inert gas, and copper oxide layer 35.

By-product 40 may be removed, for example by using a physical method. In embodiments, Ar gas including H₂ gas or pure Ar gas may be supplied to the sputter etch chamber, so that by-product 40 may be removed through the physical collision of the Ar gas or H₂ gas and by-product 40, according to embodiments.

According to the RF sputter etch process, it may be possible to adjust a roughness of copper line 30, and to improve an adhesion of capping layer 50.

Semiconductor substrate 5 may be shifted to an RF magnetron sputter chamber without interruption of the by-product removal process and/or the vacuum condition, and a capping layer 50 may be deposited to cover copper line 30 and insulation layer 10.

According to embodiments, capping layer 50 may be deposited without interrupting the by-product removal process and/or the vacuum, so that it may be possible to prevent copper oxide layer 35 from being additionally formed on copper line 30.

When capping layer 50 is deposited, gas for forming capping layer 50 may use pure Ar gas, Ar gas including hydrogen, or N₂ gas. The capping layer made from a silicon nitride layer may be deposited using a reactive sputtering method, for example using Si or SiNₓ target at room temperature or a temperature below approximately 400° C.

According to such process conditions, it may be possible to easily adjust the physical properties of capping layer 50. If the deposition temperature of capping layer 50 is less than room temperature or exceeds approximately 400° C., it may be difficult to adjust the physical properties of capping layer 50.

According to embodiments, the reactive preclean process may be used for a copper oxide layer removal process, so that the copper oxide layer may be completely removed. Further, the RF sputter etch process may be used in the by-product removal process as an In-situ process, so that it may be possible to adjust a roughness of the copper line and to improve an adhesion of the capping layer.

Consequently, it may be possible to reduce or prevent an increase in resistance due to formation of a copper oxide layer and a by-product, and device failure due to an increase in resistance may also be reduced or prevented.

Further, according to embodiments, after removing the by-product, the capping layer may be deposited without vacuum interruption, so that it may be possible to prevent the copper oxide layer from being additionally generated. Furthermore, a reactive sputter process may be used for the capping layer deposition process, so that it may be possible to easily adjust the physical properties of the capping layer.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method comprising:
forming an insulation layer on a semiconductor substrate;
forming a copper line pattern on the insulation layer, and forming a copper line;
removing a copper oxide layer that has formed on a surface of the copper line through a reactive preclean process; and
depositing a capping layer over the copper line and the insulation layer while maintaining the reactive preclean process and a vacuum condition.

2. The method of claim 1, wherein removing the copper oxide layer comprises:
arranging the semiconductor substrate including the copper line in a sputter etch chamber configured to use an Inductively Coupled Plasma (ICP) scheme;
supplying a mixture gas comprising an inert gas and a reactive gas to the sputter etch chamber; and
removing the copper oxide layer formed on the surface of the copper line through the reactive preclean process.

3. The method of claim 2, wherein the inert gas comprises at least one of He gas and Ar gas, and the reactive gas comprises H₂ gas.

4. The method of claim 2, wherein the copper oxide layer is removed through a reaction of plasma of at least one of the inert gas and the reactive gas, with the copper oxide layer.

5. The method of claim 2, comprising applying self DC bias power of −50 to −500V in the reactive preclean process.

6. The method of claim 1, wherein depositing the capping layer comprises shifting the semiconductor substrate to an RF magnetron sputter chamber without interruption of the reactive preclean process and vacuum, and the capping layer is deposited to cover the copper line and the insulation layer.

7. The method of claim 6, wherein the capping layer comprises a silicon nitride layer.

8. The method of claim 7, wherein depositing the capping layer comprises a reactive sputtering process using at least one of Si and SiNₓ as a target.

9. The method of claim 7, wherein, in depositing the capping layer, at least one of pure Ar gas, Ar gas including hydrogen, and N₂ gas is used.

10. The method of claim 7, wherein the capping layer is deposited within a temperature range of approximately 21° C. to 400° C.

11. A method comprising:
forming an insulation layer on a semiconductor substrate;
forming a copper line pattern on the insulation layer, and forming a copper line;
removing a copper oxide layer that has formed on a surface of the copper line through a reactive preclean process;
removing a by-product that has formed on the surface of the copper line by using a physical process; and
depositing a capping layer over the copper line and the insulation layer while continuing both removing the by-product and a vacuum condition.

12. The method of claim 11, wherein removing the by-product comprises:
arranging the semiconductor substrate including the copper line in a sputter etch chamber configured to use an Inductively Coupled Plasma (ICP) scheme;
supplying at least one of an inert gas including a reactive gas and pure inert gas to the sputter etch chamber to remove the by-product.

13. The method of claim 12, wherein the inert gas comprises Ar gas, and the reactive gas comprises H₂ gas.

14. The method of claim 12, wherein the by-product is removed through a physical collision of at least one of the reactive gas and the inert gas, with the by-product.

15. The method of claim 12, wherein removing the by-product is performed through the reactive preclean process and an In-situ process.

16. The method of claim 11, wherein removing the copper oxide layer comprises:
arranging the semiconductor substrate including the copper line in a sputter etch chamber configured to use an Inductively Coupled Plasma (ICP) scheme;
supplying mixture gas of an inert gas and a reactive gas to the sputter etch chamber, and removing the copper oxide layer formed on the surface of the copper line through the reactive preclean process.

17. The method of claim 16, wherein the copper oxide layer is removed through a reaction of plasma of at least one of the inert gas and the reactive gas, with the copper oxide layer.

18. The method of claim 11, wherein, in depositing the capping layer, the semiconductor substrate is shifted to a RF magnetron sputter chamber without interrupting the reactive preclean process and vacuum, and the capping layer is deposited to cover the copper line and the insulation layer.

19. The method of claim 18, wherein the capping layer comprises a silicon nitride layer.

20. The method of claim 18, wherein, in depositing the capping layer, at least one of pure Ar gas, Ar gas including hydrogen, and N₂ gas is used.
